(19) United States
(12) Patent Application Publication
(10) Pub. No.: US 2018/0108875 A1
(43) Pub. Date: Apr. 19, 2018

(54) PATTERNING APPARATUS AND ORGANIC ELECTROLUMINESCENT ELEMENT PATTERNING METHOD USING SAME

(71) Applicant: Konica Minolta, Inc., Tokyo (JP)

(72) Inventors: Naohiro OKUMURA, Ome-shi, Tokyo (JP); Hiroyuki SHINDO, Chofu-shi, Tokyo (JP); Masahiro MORIKAWA, Hachioji-shi, Tokyo (JP)

(21) Appl. No.: 15/559,447

(22) PCT Filed: Oct. 6, 2015
(86) PCT No.: PCT/JP2015/078388

§ 371 Date: Sep. 19, 2017

(30) Foreign Application Priority Data
Mar. 20, 2015 (JP) 2015-057062

(51) Int. Cl. H01L 51/56; H01L 51/00; G03F 7/20

(52) U.S. Cl. CPC H01L 51/56; G03F 7/2008; H01L 51/0018

(57) ABSTRACT

A patterning apparatus contains a UV ray generating unit; a housing that reflects and guides UV rays generated from the UV ray generating unit; and a glass mask to be irradiated with the UV rays, the glass mask being located below the housing, in which the patterning apparatus is provided with a pair of air flow generation units at opposing positions of an upper surface of the glass mask so that air is blown in parallel to the glass mask and in a direction toward a center of the glass mask through a gap between the glass mask and the housing.

### TECHNICAL FIELD

The present invention relates to a patterning apparatus and a patterning method of an organic electroluminescent element using the same. More specifically, the present invention relates to a patterning apparatus capable of performing patterning with high productivity and high dimensional accuracy, and a patterning method of an organic electroluminescent element using the same.

### BACKGROUND

At the present time, an organic luminescent panel is attracting attention as a thin light emitting material. For example, an organic luminescent element makes use of electroluminescence (EL) of an organic material (hereafter, it is also called as “an organic EL element”). It is a fully solid element which is capable of emitting light with a low voltage such as about several V to several ten V. It produces high luminance with low electric power. The organic EL element can produce high luminance at a low electric power, and it is excellent in the points of visibility, response speed, lifetime and electric power consumption. It can achieve a thin and small weight. Accordingly, it has been attracted attention in recent years for using: various display backlights; a display board such as signboard and emergency lamp; and a surface light-emitting body for illumination source.

The organic EL element has a structure in which a light emitting layer containing an organic material is located between a pair of electrodes, and emitted light in the light emitting layer is extracted to the outside through the electrode. Therefore, at least one of the pair of electrodes is composed of a transparent electrode, and the emitted light is taken out from the transparent electrode side.

In order to use an organic EL panel for a display application, it was disclosed a method of producing a patterned organic EL element. In this method, an organic functional layer of an organic EL element laminated on a glass substrate is irradiated with UV rays to deteriorate the irradiated portion. This will result in producing a patterned organic EL element having a non-light emitting portion (for example, refer to Patent document 1). Further, it is possible to form an organic EL element having a light emission pattern by changing an amount of irradiation to the organic EL element through an imagewise mask.

In proportion to an increased demand for an organic EL panel having a light emission pattern as described above, there is an increased request for increasing the screen size of the panel and high productivity of panel manufacturing. However, in this case, it is required to increase an intensity of irradiation light. It is becoming obvious the problem that is caused by the heat of the light source. Specifically, by the heat generated from the light source during UV ray irradiation, the mask on the organic EL element is heated to a high temperature to be expanded. This will cause a dimensional difference of the mask or bending of the mask. There may be produced a space between the mask and the organic EL element. The exposed image may be blurred, and it is difficult to produce a panel with high dimensional accuracy. In an extreme case, the glass mask is broken due to thermal expansion.

In order to eliminate this kind of malfunctioning caused by heat, it may be conceivable to blow air for cooling the mask. For example, Patent document 2 discloses the following technology. When the mask patter is exposed on the photosensitive substrate in the process of photolithography, a temperature controlled air flow is moved from a blowout opening to a specific direction of the projection exposure system. By this, increase of temperature is prevented. However, when air is blown from one direction as described above, it may be produced uneven air flow, and this technology is insufficient to secure the dimensional accuracy of the glass mask for production of an organic EL element that will increase the temperature. Therefore, a more efficient chilling method has been expected.

### PRIOR ART DOCUMENTS

### Patent Documents

Patent document 1: Japanese Patent Application Publication (JP-A) 2012-28335

Patent document 2: JP-A H10-289874

### SUMMARY OF THE INVENTION

### Problems to be Solved by the Invention

The present invention has been made in view of the above-described problem and situation. An object of the present invention is to provide a patterning apparatus capable of performing patterning with high productivity and high dimensional accuracy. An object of the present invention is also to provide a patterning method of an organic electroluminescent element using the same.

### Means to Solve the Problems

In order to solve the above-described problems, the present inventors have investigated the reasons of the problems. As a result, it was found out the following patterning apparatus will solve the above-described problems. At opposing positions of an upper surface of the glass mask, the apparatus is provided with a pair of air flow generation units so that, through a gap between the glass mask and the housing attached in the lower direction of the light source, air is blown in parallel to the glass mask and in a direction toward a center of the glass mask. Thus, the present invention was achieved.

That is, the above-described problems according to the present invention may be solved by the following embodiments.

1. A patterning apparatus comprising: a UV (abbreviation of ultraviolet) ray generating unit; a housing that reflects and guides UV rays generated from the UV ray generating unit; and a glass mask to be irradiated with the UV rays, the glass mask being located below the housing,

wherein the patterning apparatus is provided with a pair of air flow generation units at opposing positions of an upper surface of the glass mask so that air is blown in parallel to the glass mask and in a direction toward a center of the glass mask through a gap between the glass mask and the housing.

2. The patterning apparatus of the embodiment 1, wherein the air flow generation unit is provided with a slit form blowing section.
3. The patterning apparatus of the embodiment 1, wherein the air flow generation unit is provided with a nozzle form blowing section.
4. The patterning apparatus of any one of the embodiments 1 to 3, wherein the blown air is temperature-controlled.
5. The patterning apparatus of any one of the embodiments 1 to 4, wherein a chiller is provided at a lower part of the glass mask.
6. A method of patterning an organic electroluminescent element comprising the step of:

patterning the organic electroluminescent element by using the patterning apparatus of any one of the embodiments 1 to 5.

### Effects of the Invention

By the above-described embodiments of the present invention, it is possible to provide a patterning apparatus capable of performing patterning with high productivity and high dimensional accuracy. It is also possible to provide a method of an organic electroluminescent element using the same.

Although a formation mechanism or an action mechanism of the effects of the present invention is not clearly revealed, it is supposed as follows. The patterning apparatus is provided with a pair of air flow generation units at opposing positions of an upper surface of the glass mask so that air is blown in parallel to the glass mask and in a direction toward a center of the glass mask through a gap between the glass mask and the housing. Hereafter, the housing is simply called as a reflector or a housing. By this structure, the air blown from the opposite position will join at a center of the housing. The joined air cools the surface of the glass without lack of uniformity. Further, the joined air climbs to an upper part of the reflector and reaches the UV ray generating unit. Then, the joined air descends along the side of the reflector and circulates. As describe above, the patterning apparatus promotes air rotation (circulation) inside of the reflector. The heated air inside of the reflector is cooled, and at the same time, the reflector itself is effectively cooled.

### BRIEF DESCRIPTION OF THE DRAWINGS

FIG. 1 is a perspective view of an example of a patterning apparatus of the present invention.

FIG. 2 is a cross-section view of an example of a patterning apparatus of the present invention.

FIG. 3 is a side view of an example of an air flow generating unit provided with a slit form blowing section.

FIG. 4 is a conceptual diagram of an example of a chiller.

FIG. 5 is a cross-section view of an example of an organic EL element.

### EMBODIMENTS TO CARRY OUT THE INVENTION

A patterning apparatus of the present invention contains: a UV ray generating unit; a housing that reflects and guides UV rays generated from the UV ray generating unit; and a glass mask to be irradiated with the UV rays, the glass mask being located below the housing. The patterning apparatus is characterized in being provided with a pair of air flow generation units at opposing positions of an upper surface of the glass mask so that air is blown in parallel to the glass mask and in a direction toward a center of the glass mask through a gap between the glass mask and the housing. These technological features are common to the present invention relating to claims 1 to 6.

As an embodiment of the present invention, it is preferable that the air flow generation unit is provided with a slit form blowing section from the viewpoint of obtaining an effect of the present invention. It is also preferable that the air flow generation unit is provided with a nozzle form blowing section from the viewpoint of obtaining an effect of the present invention.

Further, it is preferable that the blown air is temperature-controlled. A cooling efficiency may be further increased by this.

As another embodiment of the present invention, it is preferable that a chiller is provided at a lower part of the glass mask from the viewpoint of obtaining an effect of the present invention.

Further, it is preferable that a method of patterning an organic electroluminescent element contains the step of: patterning the organic electroluminescent element by using the patterning apparatus of the present invention.

The present invention and the constitution elements thereof, as well as configurations and embodiments to carry out the present invention, will be detailed in the following. In the present description, when two figures are used to indicate a range of value before and after “to”, these figures are included in the range as a lowest limit value and an upper limit value.

### <<General Outline of Patterning Apparatus>>

A patterning apparatus of the present invention contains: a UV ray generating unit; a housing that reflects and guides UV rays generated from the UV ray generating unit; and a glass mask to be irradiated with the UV rays, the glass mask being located below the housing. The patterning apparatus is characterized in being provided with a pair of air flow generation units at opposing positions of an upper surface of the glass mask so that air is blown in parallel to the glass mask and in a direction toward a center of the glass mask through a gap between the glass mask and the housing.

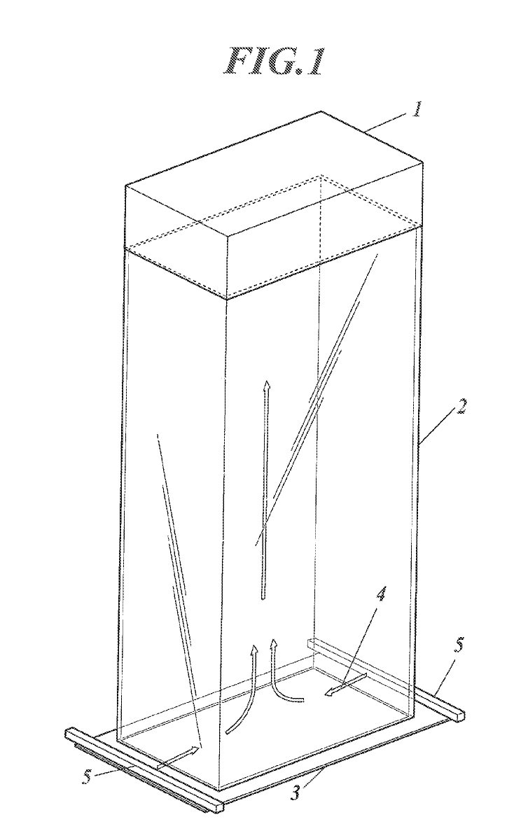

FIG. 1 is a perspective view of an example of a patterning apparatus of the present invention. UV rays emitted from a UV ray generating unit 1 pass through a housing 2 that reflects and guides the UV rays. Then, the UV rays irradiate a glass mask 3 that is located below the housing. The glass mask 3 irradiated with the UV rays becomes to have a high temperature. It thermally expands, and at the same time, the temperature of the housing and the inside of the housing is increased. It becomes difficult to perform patterning with high dimensional accuracy.

In the present invention, as a measure to resolve this problems, the patterning apparatus is characterized in being provided with a pair of air flow generation units 5 at opposing positions of an upper surface of the glass mask so that air is blown in parallel to the glass mask 3 and in a direction toward a center of the glass mask 3 through a gap between the glass mask 3 and the housing 2.

By an arrangement as described above, an air flow 4 that is blown in parallel to the glass mask 3 performs cooling of the glass surface, and the air flow joins in a center portion. The joined air flow climbs to an upper part of the housing 2 and reaches the UV ray generating unit. Then, the joined air descends along the side of the housing 2 and circulates. As describe above, the patterning apparatus promotes air rotation (circulation) inside of the housing 2. As a result, the heated air inside of the housing 2 is cooled, and at the same time, the housing 2 itself is effectively cooled. The blown air absorbs heat and circulates inside of the housing 2. Then the blown air is exhausted from the side surfaces adjacent to the surfaces provided with the air flow generation units 5.

### <<Air Flow Generating Unit>>

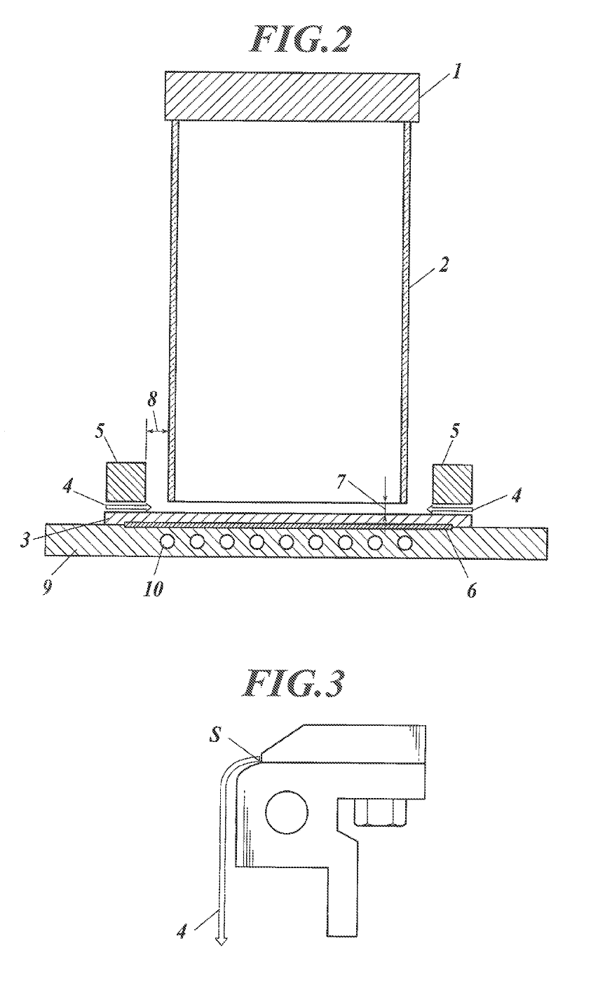

FIG. 2 is a cross-section view of an example of a patterning apparatus of the present invention. Air flow generation units 5 are arranged at opposing positions of an upper surface of the glass mask 3 so that air is blown in parallel to the glass mask 3 and in a direction toward a center of the glass mask 3 through a gap 7 between the glass mask 3 and the housing 2.

As illustrated in FIG. 2, the air flow generation unit 5 is arranged on an upper surface of the glass mask, and air is blown in parallel to the glass mask 3. The blown air flow 4 advances uniformly on the glass mask 3 and joins at a center portion of the glass mask 3. Here, “air is blown in parallel” indicate that air is blown horizontally to the surface of the glass mask 3 with an angle of ±2 degrees. When the air is blown to the surface of the glass mask 3 with an upward angle of 2 degrees or more, cooling of the glass mask will be insufficient. When the air is blown to the surface of the glass mask 3 with an downward angle of 2 degrees or more, the blown air to the glass mask will be disturbed. This will cause uneven cooling of the glass mask, or the joined air at a center portion may generate a turbulent flow inside of the housing 2. As a result, the above-described circulation may not take place, and an efficient cooling may not be obtained. This is not preferable.

The blown air to the glass mask joins at a center portion of the glass mask 3. When the blown air joins at a center portion, the glass mask 3 and the housing 2 may be uniformly cooled. Therefore, the air flow generation units 5 are arranged in parallel at opposing positions of an upper surface of the glass mask 3. Further, it is preferable that the side surfaces of the housing to be brown are also in parallel.

A distance 8 between the housing 2 and the air flow generation unit 5 is not particularly limited as long as air is effectively blown to the housing. The distance 8 is preferably in the range of 10 to 200 mm. More preferably, it is in the range of 50 to 100 mm. The length of the air flow generation unit is preferably to be the same or more of the width of the housing to be blown.

Air that is blown from the air flow generation unit 5 is blown in the housing through the gap 7 between the glass mask 3 and the housing 2. This gap 7 has a function of an inlet of air to the inside of the housing. It affects efficient circulation of the blown air inside of the housing. The size of the gap is preferably in the range of 2 to 20 mm. Preferably, it is in the range of 3 to 10 mm. When the gap is 20 mm or less, air circulation in the housing 2 is efficiently performed, and when the gap is 2 mm or more, a sufficient amount of air may be obtained.

Further, a pair of air flow generation units 5 is preferably located in a symmetrical position with respect to the housing 2 and a center portion of the glass mask. In addition to the cooling by the blown air from the air flow generation unit, it is preferable to provide a chiller 9 having a water cooling tube under the glass mask.

### <Blowing Section>

In order to perform air circulation inside of the housing 2, and to effectively cool the glass mask and the housing, it is preferable that the air flow generating unit is provided with a slit form or a nozzle form blowing section. Among them,

the air flow generating unit provided with a slit form blowing section is more preferable.

FIG. 3 is a side view of an example of an air flow generating unit provided with a slit form blowing section. An air flow generating unit provided with a slit form blowing section S is capable of blowing an air flow 4 of la layer form. For example, air jetted from a thin slit having a gap of about 50 to 100 μm with a high speed, will embroil a large amount of the surrounding air and it is capable of blowing air of a layer form. By blowing air of a layer form as described above, it will effectively cool the glass mask and the housing.

Instead of the slit form blowing section, it may be used an air flow generating unit provided with a nozzle form blowing section. In that case, a larger number of nozzles is preferable. It is preferable that a number of nozzles is one per an interval of 5 to 20 mm. A diameter of the nozzle may be suitably adjusted.

A commercially available apparatus may be used for an air flow generating unit provided with a slit form blowing section or a nozzle form blowing section for a blowing section. For example, it may be used Layer air flow generator type 750 (made by Sanwa Enterprise, Inc.) or Blower knife air nozzle (made by Spraying Systems Japan, Co. Ltd.).

It is preferable that an amount of air blown from each of a pair of blowing sections is the same. An amount of air is made to be 1,000 to 40,000 L/min. An air flow generating unit is preferably connected to an air compressor. In accordance with the irradiation amount of UV rays, the air may be suitably adjusted to have a required airflow and velocity. As an air compressor, a known compressor may be used.

The blown air is preferably temperature-controlled. A cooling efficiency may be increased by using air that is temperature-controlled to be about 5 to 15 degrees when needed.

<<Housing that Reflects and Guides Light>>

A housing that reflects and guides light (reflector) has a function of preventing decrease of an intensity of UV rays radiated from the UV ray emission unit, and making UV rays to irradiate a glass mask with uniform light intensity. Therefore, it is preferable that the interior of the housing is covered with a reflective material. As a reflective material, it may be used a metallic material since it has a heat resistivity and durability. Aluminum may be preferably used because it has a light weight.

The height and bottom area of the housing are not particularly limited as long as the housing is provided with a UV ray emitting unit on the upper portion and has a gap between the glass mask at the lower end of the housing. The height and bottom area of the housing may be decided according to the size of the organic EL panel that is irradiated with UV rays. The bottom area of the housing is preferably larger than the pattern to be produced.

The present invention is effective for a large sized organic EL panel during cooling of a large amount of UV ray irradiation. It is effective for producing an organic EL panel having a size of 0.1 to 7 m², for example. Further, by the present invention, it is possible to perform patterning with high dimensional accuracy. Therefore, a plurality of organic EL panels having the same pattern may be produced with one time UV irradiation. Thus it may increase productivity.

A height of the housing may be suitably adjusted based on an amount of UV rays, and unevenness of irradiated amount of light. For example, the height may be about 0.5 to 5 m.

### <<UV Ray Emitting Unit>>

A light source that emits UV rays is provided in a UV ray emitting section. A kind of the light source is not limited in particular as long as it is a light source that emits required amount of UV rays. Examples of a light source are: an ultra-high pressure mercury lamp, a high pressure mercury lamp, a low pressure mercury lamp, a carbon ark, a metal halide lamp, a xenon-ark lamp, a carbon-ark lamp, an excimer lamp, an UV ray laser. It may be used UV rays in the range of 100 to 400 nm, preferably in the range of 200 to 400 nm emitted from these light source.

Although it depends on the size of the organic EL panel, it may be irradiated with an intensity of radiation of 20 to 3,600 J/cm². The time of UV irradiation is preferably in the range of 5 to 300 seconds.

### <<Glass Mask>>

A glass mask has a function of changing an amount of light irradiated to an organic EL element. By using a known mask materials that is capable of changing an amount of transmitted UV rays, it is possible to form a glass mask having a negative pattern on a glass substrate. An organic EL panel provided with an emission pattern may be produced by irradiating UV rays through this glass mask to an organic EL element. For example, a photographic image may be produced by using a black and white negative image made of silver particles dispersed in a gelatin film.

The substance for the glass substrate is not limited in particular. It may be used known glass substances used for optical application or substrate application. Specific examples are: glass ceramics such as aluminosilicate glass, soda lime glass, soda aluminosilicate glass, aluminoborosilicate glass, borosilicate glass, quartz glass, chain silicate glass, crystallized glass; phosphate type glass; and lanthanum type glass.

Among them, preferable are glasses having a small expansion coefficient. Soda lime glass and quartz glass are preferably used. A thickness of a glass mask is not limited in particular. It may be used a glass mask having a thickness of 3 to 10 mm.

Here, “a pattern” designated a design (a design or a figure of a drawing), a character, or an image indicated by an organic EL panel. “Patterning” is an action to put an organic EL panel in possession of these pattern indicating functions.

“An emission pattern” is a generating source having a function of indicating a predetermined design (a design or a figure of a drawing), a character or an image, which has been given to the organic EL element for emitting light by changing an emission intensity (brightness) depending on the location of the emission surface based on a predetermined a predetermined design (a design or a figure of a drawing), a character or an image when the organic EL panel is lighted.

### <<Chiller>>

In addition to cooling by the blown air from the air flow generating unit, it is preferable that a chiller is provided at a lower part of the glass mask.

Here, “a chiller” designates an apparatus that circulates a heating medium and keeps an object to be a predetermined temperature. The chiller may be suitably used when the temperature of the glass mask becomes 100° C. or more. Further, when the temperature of the glass mask reaches 150° C., for example, the irradiation of UV rays may be interrupted and the temperature of the glass mask may be decreased to room temperature. A chiller is preferably installed in the place adjacent to the under surface of an organic EL element which is irradiated with UV rays.

Although a known chiller may be used for a chiller, a water cooling chiller is preferably used since it is simple and efficient.

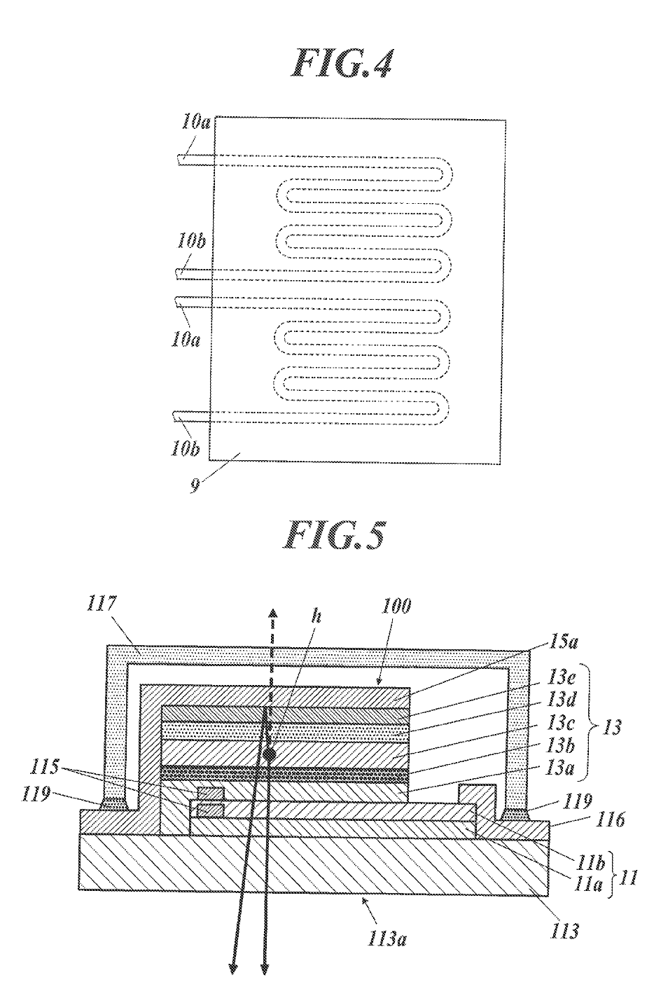

FIG. 4 is a conceptual diagram of an example of a chiller. FIG. 4 is an example of an chiller 9 that flows circulating water in two circulating systems. Cold water is introduced in a water cooling tube (introduction) 10a and it is discharged from a water cooling tube (discharge) 10b. The discharged water is cooled again and it is circulated. Thus, it is possible to cool an organic EL element that is irradiated with UV rays.

A substance used for a chiller is preferably one having high heat conductivity. For example, aluminum may be preferably used.

### <<Organic Electroluminescent Element>>

An organic EL element relating to the present invention is provided with one or a plurality of organic functional layers interposed between a pair of electrodes. An organic functional layer according to the present invention designates a layer containing an organic compound. For example, it may be cited: a hole injection layer, a hole transport layer, a light emitting layer (including: a blue light emitting layer, a green light emitting layer, and a red light emitting layer), an electron transport layer, and an electron injection layer.

An organic EL element according to the present invention may have a variety of constitutions. An example thereof is illustrated in FIG. 5. Here, FIG. 5 is drawn for explanation and the aspect ratio of the drawing is no accurate.

As illustrated in FIG. 5, an organic EL element 100 relating to the present invention is formed on a substrate 113. From the side of the substrate 113, the following are sequentially laminated: a first electrode (transparent electrode) 11, organic functional layers 13 composed of organic materials; and a second electrode (counter electrode) 15a. At an edge of the first electrode 11 (composed of an underlayer 11a and an electrode layer 11b) a taking out electrode 116 is formed. The first electrode 11 and an outer power source (not illustrated) are electrically connected through the taking out electrode 116. The organic EL element 100 is configured in a manner that emitted light (emission light h) is extracted at least from the side of the substrate 113.

The layer structure of the organic EL element 100 is not limited in particular. The layer structure may be a generally known one. Here, the first electrode 11 is made to function as an anode (a positive pole), and the second electrode 15a is made to function as a cathode (a negative pole). In this case,

an example of organic functional layers 13 is sequentially formed from the side of the first electrode 11 (anode): a hole injection layer 13a/a hole transport layer 13b/a light emitting layer 13c/an electron transport layer 13d/an electron injection layer 13e. Among them, it is essential that the organic functional layers 13 have at least the light emitting layer 13c composed of an organic material. The hole injection layer 13a and the hole transport layer 13b may be made as a hole transport-injection layer. The electron transport layer 13d and the electron injection layer 13e may be made as an electron transport-injection layer.

The organic functional layers 13 may be laminated with a hole blocking layer and an electron blocking layer according to necessity other than these layers. Further, the light emitting layer 13c may be provided with color light emitting layers each producing emission light having each wavelength region. These color light emitting layers each may have a laminated structure through a non-light emissive intermediate layer. The intermediate layer may function as a hole blocking layer or an electron blocking layer. Further, the second electrode 15a (cathode) may have a laminated structure according to necessity. In these constitutions, only the portion of the organic functional layers 13 interposed between the first electrode 11 and the second electrode 15a is a light emitting region of the organic EL element 100.

Moreover, in the layer structures as described above, an auxiliary electrode 115 may be formed adjacent to the electrode layer llb of the first electrode 11 for the purpose of achieving lower resistance of the first electrode 11.

The organic EL element having a constitution as described above is sealed with a sealing material 117 on the substrate 113 for the purpose of preventing degradation of the organic functional layers 13 composed of an organic material. This sealing material 117 is fixed on the side of the substrate 113 through an adhesive 119. Provided that an edge portion of the first electrode 11 (taking out electrode 116) and an edge portion of second electrode 15a are formed in an exposed condition from the sealing material 117 while keeping a insulation state with each other by the organic functional layers 13 on the substrate 113.

The substances used for each layer that composes an organic EL element may be generally known substances.

### EXAMPLES

The present invention will now be described with reference to examples, however, the present invention is not limited thereto. In examples, the indication of “part” or “%” is used. Unless particularly mentioned, it represents “mass part” or “mass %”.

### [Production of Organic EL Element]

### <<Production of Organic EL Element 101>>

A nitrogen containing compound N-1 having the following structure was deposited as a film of 25 μm on a transparent substrate of a PET film of 75 μm thickness (Cosmo Shine A4300, made by TOYOBO Co. Ltd.) in a vacuum deposition apparatus. Subsequently, a cathode made of silver as a film of 10 nm thickness was formed by using a mask.

Subsequently, in heating boats for vapor deposition each were placed an optimum amount of material for producing an each element: CuPC (copper phthalocyanine) as a hole injection material, α-NPD as a hole transport material, CBP as a host compound in a green emitting layer, Ir(ppy)₃ as a dopant in the blue emitting layer, CBP as host compound in a green emitting layer, Ir(ppy)₃ as a dopant in the green emitting layer, Alq₃ as an electron transport material, and LiF as an electron injection material. As a heating boat for vapor deposition, it was used a resistance heating boat made of molybdenum or tungsten.

The structures of N-1, CuPC, α-NPD, CBP, Ir(ppy)₃, BAlq, and Alq₃ each are indicated below.

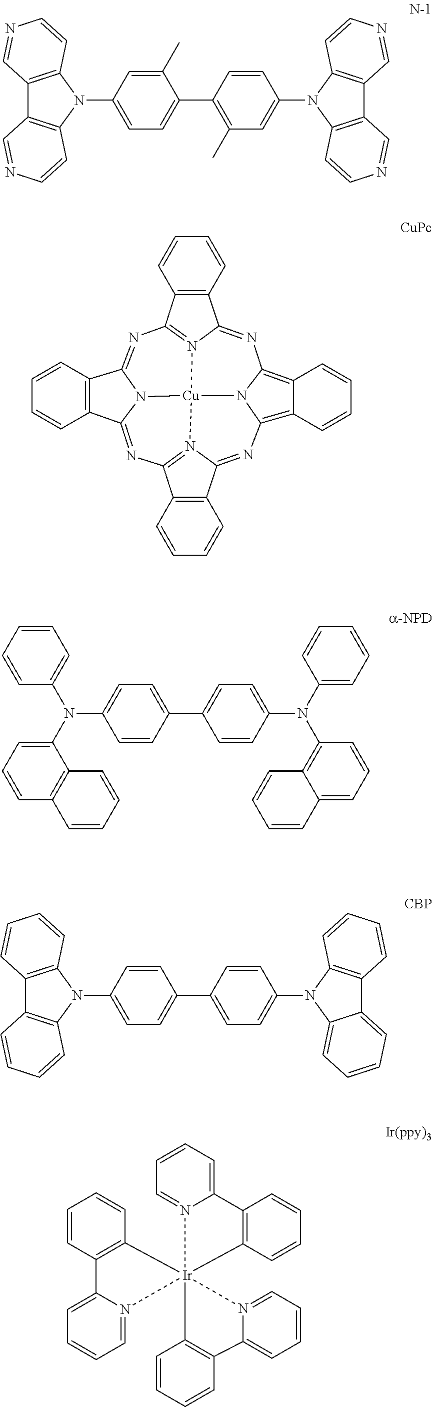

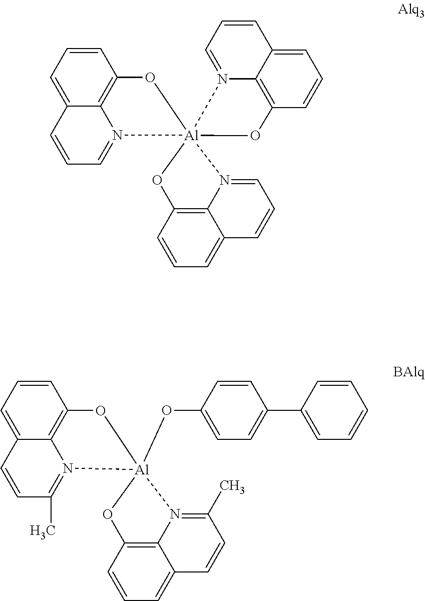

Subsequently, after reducing the pressure of the vacuum tank to 4×10⁻⁴ Pa, the heating boat containing CuPC was heated via application of electric current, and CuPC was deposited on the ITO electrode side of the transparent substrate at a deposition rate of 0.1 nm/sec, whereby it was produced a hole injection layer having a thickness of 15 nm.

Subsequently, the heating boat containing α-NPD was heated via application of electric current, and α-NPD was deposited on the hole injection layer at a deposition rate of 0.1 nm/sec, whereby it was produced a hole transport layer having a thickness of 25 nm.

Subsequently, the heating boat containing 5 mass % of Ir(ppy)₃ and CBP was heated via application of electric current, and Ir(ppy)₃ and CBP were co-deposited on the hole transport layer at a total co-deposition rate of 0.1 nm/sec, whereby it was produced a green emitting layer having a thickness of 10 nm.

Subsequently, the heating boat containing BAlq was heated via application of electric current, and BAlq was deposited on the green emitting layer at a deposition rate of 0.1 nm/sec, whereby it was produced a hole blocking layer having a thickness of 15 nm.

Subsequently, the heating boat containing Alq₃ was heated via application of electric current, and Alq₃ was deposited on the hole blocking layer at a deposition rate of 0.1 nm/sec, whereby it was produced an electron transport layer having a thickness of 30 nm.

Further, the heating boat containing LiF was heated via application of electric current, and LiF was deposited on the electron transport layer at a deposition rate of 0.1 nm/sec, whereby it was produced an electron injection layer having a thickness of 1 nm. Thus, organic functional layers were formed.

In the end, aluminum was vapor deposited on the electron injection layer to form a cathode having a thickness of 110 nm. The vapor deposited surface was covered with an epoxy resin having a thickness of 300 μm to form a sealing material. Moreover, it was covered with an aluminum foil having a thickness of 12 μm to form a protective film, and then, it was cured. All of the processes to this stage were done in a glove box under a nitrogen atmosphere (a high purity nitrogen gas atmosphere with purity of 99.999% or more) without exposing the element to the air.

Thus, an organic EL element 101 was produced. When patterning was made, it was used a size of 70×100 cm.

### <<Production of Organic EL Panel 101 Subjected to Patterning>>

### [UV Ray Irradiation]

By using a patterning apparatus illustrated in FIG. 2, an organic EL element was subjected to patterning and an organic EL panel 101 was produced. The conditions of patterning are indicated below.

### <Glass Mask>

A photosensitive material was coated on a glass substrate (soda lime glass) of a thickness of 5 mm and having a size of 81.3×137.9 cm. A line and space design having a half pitch of 0.3 mm (a line form pattern having a length of 20 mm that crosses white (transparent) and black with an interval of 0.30 mm) was arranged in a vertical, a horizontal and a diagonal (45 degrees) directions to produce a checking pattern. A large number of checking patterns were photographically exposed to the glass substrate to form a glass mask.

In the center portion of the glass mask was placed an organic EL element with facing up the emitting surface and being close contacted with the glass mask.

An organic EL panel was produced under the following conditions at an environment of room temperature of 25° C.

### <Housing>

Size: (W) 1155 mm×(D) 784.5 mm×(H) 2500 mm

Substance: It was used a housing having an aluminum sandwich structure of: reflecting plate (thickness of 1.5 mm) made of aluminum inside wall/air layer (thickness of 5 mm)/aluminum outside wall (thickness of 7.5 mm).

Gap 7 between housing for reflecting-guiding light and glass mask: 5.0 mm

### <UV Ray Generation Unit>

Light source: High pressure mercury lamp

Irradiation amount: 4 W/cm²

Irradiation time: 5 minutes

### <Air Flow Generating Unit>

An air flow generating unit having a slit form blowing section was used. The same amount of air was blown from both short sides towards the center portion of the glass mask.

Position of the slit of the blowing section: 3 mm above the glass surface

Angle of the blowing section in the air flow generating unit: parallel with respect to the surface of the glass mask

Gap 8 between the air flow generating unit and the housing:

to be 72 mm, a pair of air flow generating units were installed at the opposing positions of the short sides of the housing.

Temperature of blown air: 25° C.

Pressure of compressed air: 0.3 MPa

Consumption amount of air: 1500 L/min

### <<Production of Organic EL Panel 102 Subjected to Patterning>>

An organic EL panel 102 was produced in the same manner as production of the organic EL panel 101 except that a chiller was used for cooling with cooling water from the under surface of the organic EL element.

Chiller: By using a chiller having a water cooling tube with a diameter of 10 mmΦ in an aluminum plate having a thickness of 60 nm, it was circulated water with temperature of 20° C. at a rate of 5 m³/min.

### <<Production of Organic EL Panel 103 Subjected to Patterning>>

An organic EL panel 103 was produced in the same manner as production of the organic EL panel 102 except that the air blow from the air flow generating unit was stopped.

### <<Measurement of Organic EL Panel Size>>

### <<Production of Organic EL Panel 104 Subjected to Patterning>>

An organic EL panel 104 was produced in the same manner as production of the organic EL panel 101 except that the air blow from the air flow generating unit was stopped. That is, an organic EL panel 104 was produced without using cooling device. In this case, the glass mask was broken due to the heat from the UV ray emitting unit.

### <Measurement of Mask Size>>

A length change by thermal expansion was measured by subtracting the length of the glass mask before UV irradiation from the length of the glass mask after UV irradiation at 25° C. for 5 minutes. A change of the glass mask outer size was measured with a laser displacement meter (LK-H150, made by Keyence Co. Ltd.) during UV irradiation. The short side direction of the glass mask (the side to which air is blown) and the long side direction of the glass mask (the side to which blown air is discharged) after UV irradiation for 5 minutes each were measured as an average value. Thus, a length change by thermal expansion was obtained. The results are listed in Table 1.

TABLE 1

| | | | Change of length by | | |
|---|---|---|---|---|---|
| Organic | | | thermal expansion | | |
| EL | | | Short side | Long side | |
| Panel | Cooling | | direction | direction | |
| No. | Blown air | Chiller | (mm) | (mm) | Remarks |
| 101 | Present | Absent | 0.518 | 0.879 | Present invention |
| 102 | Present | Present | 0.345 | 0.586 | Present invention |
| 103 | Absent | Present | 0.691 | 1.172 | Comparison |

| | | | | |
|---|---|---|---|---|
| 104 | Absent | Absent | Cannot be measured | Comparison |
| | | | due to breakdown | |

From the results in Table 1, it is proved that the organic EL panel 101 of the present invention is not easily affected by heat. It is also proved that the organic EL panel 102 of the present invention produced by using chiller is further not easily affected by heat. On the other hand, the comparative organic EL panel 103 produced by cooling only with a chiller has a large amount of change in length by heat due to insufficient cooling effect

By sending an electric current to an organic EL panel, and the checking pattern of line and space having a 0.3 half pitch was payed attention. It was observed that the organic EL panels 101 and 102 of the present invention had a line form pattern in the center portion and in the peripheral portion of the panel. Although there is some decrease of brightness. On the other hand, it was not observed a line form pattern in the peripheral portion of the comparative organic EL panels 103. The line form patter was completely disappeared. Not only the checking pattern was indistinct in the peripheral portion, it was observed partial disappearance of the checking pattern in the central portion. It was observed that an uneven pattern was produced. It was assumed that the glass mask was bent and the UV irradiation was made under an insufficient close contact condition between the glass mask and the organic El element.

Further, in the production of the organic EL panel 101, when the same amount of air is blown by using a nozzle form air flow generating unit (nozzle diameter 4.0 mmΦ, placed in the short side direction of the housing at an interval of one nozzle per 10 mm) in place of the slit form air flow generating unit, it was obtained the good results comparable to the organic EL panel 101. In the production of the organic EL panel 101, when the temperature of blown air was adjusted to 10° C., it was failed to obtain the good results comparable to the organic EL panel 102 produced by using a chiller.

### INDUSTRIAL APPLICABILITY

A patterning apparatus of the present invention is capable of performing patterning with high productivity and high dimensional accuracy. It may be applied to a various displays provided with a panel produced by patterning an organic electroluminescent element.

### DESCRIPTION OF SYMBOLS

1: UV ray generating unit
2: Housing (reflector)
3: Glass mask
4: Air flow
5: Air flow generating unit
6: Organic EL element
7: Gap between glass mask and housing
8: Distance between housing and air flow generating unit
9: Chiller
10: Water cooling tube
10a: Water cooling tube (introduction)
10b: Water cooling tube (discharge)
S: Slit form blowing section
11: First electrode
11a: Underlayer
11b: Electrode layer
13: Organic functional layer
13a: Hole injection layer
13b: Hole transport layer
13c: Light emitting layer
13d: Electron transport layer
13e: Electron injection layer
15a: Second electrode
100: Organic EL element
113: Substrate
113a: Light extraction surface
115: Auxiliary electrode
116: Taking out electrode
117: Sealing material
119: Adhesive
h: Emission light

1. A patterning apparatus comprising: a UV ray generating unit; a housing that reflects and guides UV rays generated from the UV ray generating unit; and a glass mask to be irradiated with the UV rays, the glass mask being located below the housing,
wherein the patterning apparatus is provided with a pair of air flow generation units at opposing positions of an upper surface of the glass mask so that air is blown in parallel to the glass mask and in a direction toward a center of the glass mask through a gap between the glass mask and the housing.

2. The patterning apparatus of claim 1, wherein the air flow generation unit is provided with a slit form blowing section.

3. The patterning apparatus of claim 1, wherein the air flow generation unit is provided with a nozzle form blowing section.

4. The patterning apparatus of claim 1, wherein the blown air is temperature-controlled.

5. The patterning apparatus of claim 1, wherein a chiller is provided at a lower part of the glass mask.

6. A method of patterning an organic electroluminescent element comprising the step of:
patterning the organic electroluminescent element by using the patterning apparatus of claim 1.
